(19) United States
(12) Patent Application Publication
(10) Pub. No.: US 2021/0310981 A1
(43) Pub. Date: Oct. 7, 2021

(54) Addressing Nanoelectrodes in a Nanoelectrode Array

(71) Applicant: IMEC VZW, Leuven (BE)

(72) Inventors: Olivier Henry, Kraainem (BE); Arnaud Furnemont, Jandrenouille (BE); Stefan Cosemans, Leuven (BE)

(21) Appl. No.: 17/208,080

(22) Filed: Mar. 22, 2021

(30) Foreign Application Priority Data
Apr. 1, 2020 (EP) 20167573.3

(51) Int. Cl. G01N 27/327; B82Y 30/00; G11C 11/408

(52) U.S. Cl. CPC G01N 27/3278; G11C 11/4085; B82Y 30/00

(57) ABSTRACT

In a first aspect, the present disclosure relates to a system for addressing nanoelectrodes in a nanoelectrode array, the system including an array of electrode cells, each electrode cell including: an access transistor having a gate resistively coupled to a word line, a source resistively coupled to a bit line, and a drain, and a storage circuit resistively coupled to the drain and including a nanoelectrode.

### CROSS-REFERENCE TO RELATED APPLICATIONS

The present application is a non-provisional patent application claiming priority to European Patent Application No. 20167573.3, filed on Apr. 1, 2020, the contents of which are hereby incorporated by reference.

### FIELD OF THE DISCLOSURE

The present disclosure relates to nanoelectrode arrays, for example those used in molecular synthesis, and in particular to addressing the nanoelectrodes therein.

### BACKGROUND

The need for inexpensive and dense cold data storage increasingly raises interest in molecular data storage solutions, such as DNA-based storage solutions, in which stable organic molecules are synthesized to map binary information. To make such molecular data storage practical, a high synthesis throughput is sought so that a reasonable write time can be achieved. To that end, solutions have been explored in which multiple different molecules are synthesizing in parallel in an array of synthesis cells.

In order to form different molecules in the different synthesis cells, the synthesis must be made selective, i.e. the reaction needs to be enabled in a certain portion of the array and inhibited in the rest of the array. This challenge can be addressed in different ways, but the most promising approaches are based on electrodes. In such approaches, each synthesis cell typically has one or more electrodes associated therewith, with which the reaction conditions (e.g., pH) are locally controlled. US 20160354751A1 for example describes a microarray of electrodes for oligonucleotide synthesis having in excess of 12,000 electrodes in a region of about 1 cm², with a circular electrode diameter of about 44 microns and an electrode distance-to-distance of about 75 microns.

However, in order to achieve writing speeds at which the molecular data storage can become commercially viable, arrays of about one billion electrodes or more would be desired. With a factor on the order of 100,000 compared to US20160354751A1, this represents an aggressive change in scope that brings with it several complications which cannot easily be overcome. There is thus still a need in the art for solutions which address at least some of these issues.

### SUMMARY

This disclosure provides a system for addressing nanoelectrodes in a nanoelectrode array and methods associated with such a system.

In particular, an option is provided for possibly realizing the aggressive change in scope that was described in the background section. First, at a density of 12,000 electrodes/cm², a straightforward extension of the microarray of US 20160354751A1 could require an unwieldy array size of 8.3 m² to provide one billion electrodes. Conversely, the footprint is presently scaled down considerably through using nanoelectrodes (e.g. having a size of few hundred nanometers or less) rather than microelectrodes with a size of several tens of micrometers. Moreover, it was further realized that a mere size reduction might be insufficient. Indeed, perhaps less immediately apparent but possibly as important is the issue of how to address roughly one billion or more electrodes sufficiently simultaneously. After all, if the potential for each of these electrodes cannot be set within a relatively short time frame (e.g. compared to the required synthesis time), the synthesis in the synthesis cells will not be parallel and/or the required total write time will be unduly prolonged. This is true for the hypothetical 8.3 m² microarray but is even further exacerbated for an array of nanoelectrodes, where the requirements for the driving electronics (e.g. in terms of available/allowable space, current, power, heat production, etc.) are typically strict.

It is a potential advantage of embodiments of the present disclosure that compact (i.e. densely packed) electrode arrays can be formed.

It is a potential advantage of embodiments of the present disclosure that a vast number of nanoelectrodes can be individually addressed. It is a potential advantage of embodiments of the present disclosure that the nanoelectrodes can be set relatively simultaneously with respect to the typical time frame needed for a chemical reaction (e.g. the chemical reaction may occur on a time frame in the order of seconds, while all the nanoelectrodes may be set within a time fame in the order of tens of milliseconds). It is yet a further potential advantage of embodiments of the present disclosure that the potential for the nanoelectrodes can be quickly set, re-set, and/or overwritten.

It is a potential advantage of embodiments of the present disclosure that addressing the nanoelectrodes can be performed at low power (e.g. in the order of up to 500 mW) and/or low voltage (e.g. about 0.5 V to 1 V in addition to the voltage difference between the lowest and highest potential set for the nanoelectrodes, e.g. between an inactive and an active nanoelectrode or between a counteractive and an active nanoelectrode).

It is a potential advantage of embodiments of the present disclosure that the electrode cells have very long (e.g. almost infinite) endurance; i.e. they do not easily break down, even after extended use (e.g. the access transistor can be opened and the storage circuit charged about 10¹⁵ times or more before breaking down).

It is a potential advantage of embodiments of the present disclosure that the potential of the nanoelectrodes can be selected and set relatively freely (e.g. the potential is not limited to a discrete number of values). It is a potential advantage of embodiments of the present disclosure that the potential of different nanoelectrodes in the nanoelectrode array can be individually selected and set.

It is a potential advantage of embodiments of the present disclosure that well-developed strategies and fabrication methods that have been developed for dynamic random-access memory (DRAM) can be used.

It is a potential advantage of embodiments of the present disclosure that the reaction conditions can be physically and/or electrochemically confined.

It is a potential advantage of embodiments of the present disclosure that a vast number of different molecules (e.g. DNA) can be synthesized in parallel. It is a further advantage of embodiments of the present disclosure that an effective DNA data storage can be realized.

It is a potential advantage of embodiments of the present disclosure that back end of line (BEOL) electrode cell access transistors can be used, thereby allowing the use of the front end of line (FEOL) region entirely for peripheral circuits.

It is a potential advantage of embodiments of the present disclosure that—in setting the potential of the nanoelectrodes—also control over the current of the nanoelectrodes can be achieved. It is a further advantage of embodiments of the present disclosure that systems can be realized in which the nanoelectrodes can be operated potentiostatically, galvanostatically, or potentiodynamically.

In a first aspect, the present disclosure relates to a system for addressing nanoelectrodes in a nanoelectrode array, the system comprising an array of electrode cells, each electrode cell comprising: (i) an access transistor having a gate resistively coupled to a word line, a source resistively coupled to a bit line, and a drain; and (ii) a storage circuit resistively coupled to the drain and comprising a nanoelectrode.

In a second aspect, the present disclosure relates to a use of a system as defined in any embodiment of the first aspect, for addressing nanoelectrodes in a nanoelectrode array.

In a third aspect, the present disclosure relates to a method for addressing nanoelectrodes in a system according to any embodiment of the first aspect, comprising: (a) selecting a potential for each nanoelectrode, and (b) setting the selected potentials by, for each electrode cell, opening the access transistor by asserting the word line and charging the storage circuit to the selected electrode potential by aptly biasing the bit line.

In a fourth aspect, the present disclosure relates to a method for synthesizing a molecule, comprising: (a) setting the potential of one or more nanoelectrodes using the method according to any embodiment of the third aspect, and (b) contacting one or more reagents to the nanoelectrodes; thereby locally forming an electrochemical environment for mediating the synthesis.

Particular aspects of the disclosure are set out in the accompanying independent and dependent claims. Features from the dependent claims may be combined with features of the independent claims and with features of other dependent claims as appropriate and not merely as explicitly set out in the claims.

The above and other characteristics, features and advantages of the present disclosure will become apparent from the following detailed description, taken in conjunction with the accompanying drawings, which illustrate, by way of example, the principles of the disclosure. This description is given for the sake of example only, without limiting the scope of the disclosure. The reference figures quoted below refer to the attached drawings.

### BRIEF DESCRIPTION OF THE FIGURES

The above, as well as additional, features will be better understood through the following illustrative and non-limiting detailed description of example embodiments, with reference to the appended drawings.

FIG. 1 is a schematic 3D view of an array for molecular synthesis, according to an example.

FIG. 2 is a schematic vertical cross-section of the array in FIG. 1, according to an example.

FIG. 3 is a schematic 3D view of an array for molecular synthesis, according to an example.

FIG. 4 is a schematic vertical cross-section of the array in FIG. 3, according to an example.

FIG. 5 is a schematic top view of several nanoelectrodes, according to an example.

FIG. 6 is a schematic top view of several nanoelectrodes, according to an example.

FIG. 7 is a schematic top view of several nanoelectrodes, according to an example.

FIG. 8 schematically depicts an array of electrode cells, according to an example.

In the different figures, the same reference signs refer to the same or analogous elements.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The present disclosure will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the disclosure.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the disclosure described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable with their antonyms under appropriate circumstances and that the embodiments of the disclosure described herein are capable of operation in other orientations than described or illustrated herein.

“Similarly, it is to be noticed that the term “coupled” should not be interpreted as being restricted to direct connections only. The terms “coupled” and “connected,” along with their derivatives, may be used. It should be understood that these terms are not intended only as synonyms for each other. Thus, the scope of the expression “an entity A coupled to an entity B” should not be limited to situations wherein an output of entity A is directly connected to an input of entity B. It also can mean that there exists a path between an output of A and an input of B, which may be a path including other entities or means. “Coupled” may thus mean that two or more elements are either in direct contact (i.e. they may be connected), or that two or more elements are not in direct contact with each other but yet still co-operate or interact with each other.

Reference throughout this specification to “one embodiment” or “an embodiment” means that a particular feature, structure or characteristic described in connection with the embodiment is included in at least one embodiment of the present disclosure. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly, it should be appreciated that in the description of embodiments of the disclosure, various features of the disclosure are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed disclosure requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this disclosure.

Furthermore, while some embodiments described herein include some but not other features included in other embodiments, combinations of features of different embodiments are meant to be within the scope of the disclosure, and form different embodiments, as would be understood by those in the art. For example, in the following claims, any of the claimed embodiments can be used in any combination.

In the description provided herein, numerous specific details are set forth. However, it is understood that embodiments of the disclosure may be practiced without these specific details. In other instances, well-known methods, structures and techniques have not been shown in detail in order not to obscure an understanding of this description.

Reference will be made to transistors. These are devices having a first main terminal (e.g. a source or collector), a second main terminal (e.g. a drain or emitter) and a control terminal (e.g. a gate or base) for controlling the flow of electrical charges between the first and second main terminals.

For a better qualitative understanding, an analogy with dynamic random-access memory (DRAM) and its operation will herein occasionally be made. It shall be clear that this ex post facto analogy—which is given here only to aid the reader's understanding—should not be abused to diminish the inventive step of the present disclosure. Indeed, the realization that circuits which are well known in DRAM can—with adaptations—be repurposed to solve a technical problem faced in nanoelectrode arrays, forms an appreciable part of the inventive effort achieved by the present inventors.

In a first aspect, the present disclosure relates to a system for addressing nanoelectrodes in (e.g. arranged as) a nanoelectrode array, the system comprising an array of electrode cells, each electrode cell comprising: (i) an access transistor having a gate resistively coupled to a word line, a source resistively coupled to a bit line, and a drain; and (ii) a storage circuit resistively coupled to the drain and comprising a nanoelectrode.

It was surprisingly conceived within the present disclosure that addressing of nanoelectrodes in a nanoelectrode array can be realized in an effective manner by resistively coupling each nanoelectrode—as part of a storage circuit—to the drain of an access transistor. Here, the analogy can be made with DRAM: the present electrode cell can be likened to a DRAM memory cell having a nanoelectrode coupled to the storage side thereof. Based on such an electrode cell, the potential of the nanoelectrodes can then be set using similar strategies (cf. infra) as have been developed to write to DRAM memory cells, including—optionally—periodically refreshing the set potentials.

In embodiments, the array of electrode cells may comprise one or more rows, the electrode cells in a row being linked by a common word line, and/or one or more columns, the electrode cells in a column being linked by a common bit line. In embodiments, the electrode cells may be arranged in a cubic packing, hexagonal packing, or any other suitable arrangement.

In embodiments, the storage circuit may comprise the nanoelectrode and an electrical connection (e.g. wire) resistively coupling the nanoelectrode to the drain. In embodiments, the storage circuit may further comprise a capacitor. In embodiments, the capacitor may have a terminal resistively coupled to both the drain and the nanoelectrode (i.e. the same terminal may be coupled to both). In some embodiments, the capacitor may be a separate (i.e. distinct) capacitor; i.e. the capacitor may be an electrical component solely dedicated to that role. In other—alternative or complementary—embodiments, an electrical component may perform the role of capacitor and one or more further functions. For example, a capacitor may be formed about the electrical connection coupling the drain to the nanoelectrode, so that the ensemble simultaneously fulfils the role of the electrical connection and capacitor. Such a capacitor could for instance be achieved by wrapping the electrical connection with a dielectric and then wrapping a counter-electrode about dielectric. In yet other—alternative or complementary—embodiments, through their inherent parasitic capacitance (e.g. wire capacitance), the storage circuit and/or the electrical connection as such may be regarded as a capacitor.

In embodiments, the storage circuit may have a capacitance of at least 0.01 fF, at least 1 fF, at least 10 fF, at least 20 fF, such as at least 30, 50, 100, 200 or 500 fF. Especially in combination with a suitable refresh rate (e.g. 64 ms or more; cf. infra), such a capacitance—in particular in the order of 10 fF (e.g. about 30 fF) or more—should typically allow storage of enough charge in order to drive an electrochemical reaction for a sufficient period of time (e.g. until the next refresh) to for instance enable or disable a synthesis reaction within a synthesis cell above the nanoelectrode. In embodiments, the capacitance of the storage circuit may be partially or entirely due to a parasitic capacitance (e.g. wire capacitance) of the storage circuit. In embodiments, the capacitor may have a capacitance of at least 0.01 fF, at least 1 fF, at least 10 fF, at least 25 fF, at least 30 fF, such as at least 30, 50, 100, 200 or 500 fF. Note that there is also a practical upper limit to the capacitance in that charging the storage circuit takes longer when the capacitance thereof is higher. As such, a favorable range for the capacitance may be from about 20 fF to about 500 fF when using front-end-of-line (FEOL) access transistors, and from about 1 fF to 25 fF when using back-end-of-line (BEOL; cf. infra) transistors.

In embodiments, the nanoelectrode may have a size (e.g. a width or diameter) of 1 μm or less, 500 nm or less, 250 nm or less, 150 nm or less, such as 100 nm or less. In embodiments, the nanoelectrodes (e.g. the nanoelectrode array) may have a pitch (i.e. a center-to-center distance between adjacent nanoelectrodes) of 1 μm or less, 500 nm or less, 250 nm or less, 150 nm or less, such as 100 nm or less. The currently most advanced DRAM nodes, for example, use a hexagonal lay-out (e.g. of the capacitors) with a pitch of about 30 nm, illustrating that the aforementioned dimensions are well within the current technological capabilities.

In embodiments, the access transistors—and optionally the electrode cells as a whole—may be formed on a semiconductor substrate (e.g. a Si, Ge, SiGe or semiconductor-on-insulator substrate). In embodiments, the access transistor may be a planar transistor (e.g. a planar field-effect transistor, planar FET) or a vertical transistor (e.g. a vertical FET, VFET). In embodiments, the access transistor may be a back end of line (BEOL) transistor; i.e. a transistor formed during the BEOL stage of semiconductor processing. The access transistor may for example be a thin film metal-oxide-semiconductor FET (MOSFET), such as those based on an indium gallium zinc oxide (IGZO), polysilicon, or 2D material (e.g. MoS₂, MoSe₂, MoTe₂, WS₂ or WSe₂) thin film. The use of BEOL access transistors can allow dedication of the front end of line (FEOL) region below the electrode cell array for peripheral circuits (e.g. write drivers, refresh circuits and/or data transfers).

In embodiments, the array of electrode cells may number 30,000 electrode cells or more, 100,000 or more, 250,000 or more, 1,000,000 or more, 10,000,000 or more, such as up to 16,000,000 or more. In embodiments, the array may have a size (e.g. a block size) on the order of 256 (e.g. along the wordline direction) by 128 (e.g. along the bitline direction) or more, 1,024 by 256 or more, or 16,384 by 1,024 or more. In embodiments, the system may comprise a plurality of electrode cell arrays. By having multiple electrode cell arrays which can be written simultaneously (i.e. akin to sub-banking in DRAM), the throughput at low energy can potentially be improved. In embodiments, the system may count a total of 30,000 electrode cells or more, 100,000 electrode cells or more, 1,000,000 or more, 10,000,000 or more, 100,000,000 or more, 1,000,000,000 or more, such as up to 1,000,000,000,000 or more.

In embodiments, any feature of any embodiment of the first aspect may independently be as correspondingly described for any embodiment of any of the other aspects.

In a second aspect, the present disclosure relates to a use of a system as defined in any embodiment of the first aspect, for addressing nanoelectrodes in a nanoelectrode array.

In embodiments, the use may be for operating at least one of the nanoelectrodes potentiostatically, galvanostatically or galvanodynamically (cf. infra). In embodiments, the use may be for operating at least one of the nanoelectrodes potentiostatically, galvanostatically or galvanodynamically within a predetermined margin. Thus, the nanoelectrode may—within the predetermined margin (i.e. plus or minus the margin)—respectively be maintained at a constant potential, maintained at a constant current or its potential may be swept at a constant rate. The predetermined margin may be 30% or less, 20% or less, 10% or less, 5% or less, 2% or less, such as 1% or less.

In embodiments, any feature of any embodiment of the second aspect may independently be as correspondingly described for any embodiment of any of the other aspects.

In a third aspect, the present disclosure relates to a method for addressing nanoelectrodes in a system according to any embodiment of the first aspect, comprising: (a) selecting a potential for each nanoelectrode, and (b) setting the selected potentials by, for each electrode cell, opening the access transistor by asserting the word line and charging the storage circuit to the selected electrode potential by aptly biasing the bit line.

In embodiments, step b may further comprise closing the access transistor after having charged the storage circuit. In embodiments, the access transistor may be closed before opening a further access transistor.

In embodiments, step b may comprise charging the storage circuit to the selected electrode potential by biasing the bit line to a potential (e.g. with respect to ground) of −3 V to 3 V, −2 V to 2 V, such as from −1 V to 1 V. In embodiments, the potential selected in step a and set in step b may differ for different nanoelectrodes. The potential that can be selected and set is generally not limited to a discrete set of values (e.g. such as in a digital case), but can be essentially any of a continuous set of values (within the margins of experimental accuracy). This can allow selection of the potential based on the specific requirements for each nanoelectrode. For example, as a DNA strand is further expanded (cf. Example 4) away from the nanoelectrode, the generated H⁺ concentration may need to rise in order to achieve the same deprotection efficiency on the further away protection group. As such, the degree to which the storage circuit is charged may need to be raised as a function of the length of the DNA strand. Moreover, different DNA strands across the array may have a different length, so that the stored charge may differ from one storage circuit to the next. Moreover, the ideal potential for a nanoelectrode may depend on the state of the neighboring cells. Such needs can be accommodated within the present disclosure through changing the biasing potential and/or charging time used.

In embodiments, step b may comprise setting a plurality of the selected electrode potentials simultaneously by—for a row of electrode cells linked by a common word line-opening all access transistors by asserting the common word line and—for each electrode cell in the row—charging the storage circuit by aptly biasing the bit line. In embodiments, step b may further comprise closing all the access transistors in the row after having charged the storage circuits. In embodiments, the access transistors in the row may be closed before opening a further row of access transistors. Strategies akin to those that have been used to quickly write to a vast number of memory cells in DRAM can be used in the present disclosure to quickly (e.g. virtually simultaneously compared to the time frame of the chemical reactions that are being considered) address a large number of nanoelectrodes.

After having charged the storage circuit, the stored charge can be used to drive the nanoelectrode, e.g. to perform an electrochemical reaction. In doing so, the stored charge will typically be used over time. Moreover, even if not expended to drive an electrochemical reaction, the stored charge will typically (e.g., slowly, e.g. in the order of milliseconds) leak out of the storage circuit (e.g. through the reaction medium, transistor or capacitor) and thus anyway deplete over time. Thus, after the storage circuit has been charged, the nanoelectrode will typically experience a potential profile which decays over time.

In embodiments, the method may comprise a further step c of: (c) refreshing the selected potentials by repeating step b. In embodiments, step c may comprise repeating step b periodically, such as periodically for a predetermined duration (e.g. for a duration needed to complete a chemical reaction). Refreshing the selected potentials can allow for recovery of the decaying potential profile. In doing so, the experienced potential profile can be turned into a periodic function. Depending on the interplay between the characteristics of the storage circuit (e.g. its capacitance), the retention time/decay rate (as affected by actively using up the stored charge or through inevitable depletion) and the refresh rate (i.e. the duration between the start times of subsequent repetitions of step b), the amplitude of the periodic function can be made larger (e.g. corresponding to more pronounced potential pulses) or smaller (e.g. corresponding to an overall flatter potential profile). In embodiments, the refresh rate may be 5 ms to 500 ms, 20 ms to 250 ms, 35 ms to 150 ms, 40 ms to 100 ms, 55 ms to 75 ms, such as 64 ms. A typical refresh rate for DRAM memory is, for example, 64 ms, so current refresh circuits are already adapted to such a refresh rate.

In step a, the potential for each nanoelectrode may typically be selected in view of the goal that is to be achieved for that nanoelectrode. This goal may for example include whether the nanoelectrode is to be set active, neutral, or counteractive (cf. infra); but it can also include how the nanoelectrode is to be controlled, for example potentiostatically (i.e. aiming to maintain the nanoelectrode at a constant potential), galvanostatically (i.e. aiming to maintain the nanoelectrode at a constant current) or potentiodynamically (e.g. aiming to sweep the nanoelectrode's potential at a constant rate). Operating the nanoelectrode at a constant potential—within a predetermined margin (cf. supra)—can for example be achieved by refreshing the set potential before it has decayed (cf. supra) below this margin. Operating the nanoelectrode at a constant current—again within a predetermined margin—may be achieved using a comparable strategy, through an adaptive refresh. Here it may not suffice to simply set the potential back to the previously set value, but rather the storage circuit should be charged in view of the charge that has been expended since the previous set action; meaning that the potential to be set may need to be adapted for each refresh. This can for example be achieved by first reading out the remaining charge (remaining potential) through the bit line at the start of the refresh and determining therefrom the new potential that is to be set in order to maintain a (relatively) constant current. Another strategy to operate the nanoelectrode at a constant current within a predetermined margin is to make use of capacitive charge injection through the capacitor (if present), by connecting the capacitor's second terminal to an inject line. In that case, a linear voltage ramp on the inject line will for example result in a fixed charge influx into the storage circuit. For nanoelectrodes set to active (e.g. set to a high potential),—depending on the specific parameters chosen—a balance between incoming and outgoing charge can be achieved, resulting in a relatively constant current. For nanoelectrodes set to inactive (e.g. set to a low potential), the incoming charge will charge the storage circuit, but as long as the potential thereby developed is lower than needed to drive the reaction, this reaction will not be enabled. During a refresh, this built-up charge can then again be released through the word line, so that the inactive nanoelectrodes can be kept inactive by using a suitable refresh rate. In embodiments, these strategies for maintaining a (relatively) constant current can also be combined.

In embodiments, step b may comprise setting the nanoelectrode to be active, neutral, or counteractive. Active, neutral, and counteractive here refer to the electrochemical activity of the nanoelectrode: an active electrode has a suitable potential for bringing about a particular electrochemical reaction, a counteractive electrode has a suitable potential for bringing about a different reaction (e.g. the opposite reaction, in so far as the electrochemical reaction is reversible), and an inactive electrode has an intermediate potential which is neither sufficient to bring about the particular electrochemical reaction nor its opposite. In embodiments, step a may comprise selecting more negative potentials for the nanoelectrodes which are to be active, and intermediate potentials for the nanoelectrodes which are to be inactive and/or more positive potentials for the nanoelectrodes which are to be counteractive. In other embodiments, step a may comprise selecting more positive potentials for the nanoelectrodes which are to be active, and intermediate potentials for the nanoelectrodes which are to be inactive and/or more negative potentials for the nanoelectrodes which are to be counteractive. In the above, rather than referring to absolute values, the potentials are expressed relative to one another. Indeed, the specific potential values will, among other variations, typically depend on the reference point that is selected (e.g. ground or a counter-electrode contacting the reaction medium). As such, a more negative potential may in some instances still be positive, etc. Regardless of the reference point selected however, suitable potentials for setting a nanoelectrode to active, inactive, or counteractive for a particular electrochemical reaction can typically be calculated (e.g. based on theory and modelling) or can be derived by relatively simple and straightforward trial-and-error.

In embodiments, any feature of any embodiment of the third aspect may independently be as correspondingly described for any embodiment of any of the other aspects.

In a fourth aspect, the present disclosure relates to a method for synthesizing a molecule, comprising: (a) setting the potential of one or more nanoelectrodes using the method according to any embodiment of the third aspect, and (b) contacting one or more reagents to the nanoelectrodes; thereby locally generating reaction conditions for mediating the synthesis.

Synthesizing the molecule may typically be performed in a reaction medium; such as a fluid (e.g. a liquid or gas). In embodiments, the reaction medium may contact the nanoelectrodes. In embodiments, the reaction medium may comprise the one or more reagents. In embodiments, the method may further comprise contacting a counter-electrode to the reaction medium.

In embodiments, the molecule to be synthesized may be a biomolecule; e.g. a biopolymer such as (synthetic) DNA. In embodiments, the method may be for forming a DNA data storage (i.e. a data storage system in which data is encoded in DNA) or for spatial transcriptomics, for example, DNA data storage.

In embodiments, the step b may be started before, together with, or after starting step a. In embodiments, step a and step b may at least partially overlap in time. In other words, regardless of which step is performed first, the nanoelectrodes are most commonly (still) at a certain potential when the reagents are (still) in contact with the nanoelectrodes.

In embodiments, mediating the synthesis may comprise locally enabling or disabling the synthesis. In embodiments, mediating the synthesis may comprise directly or indirectly mediating the synthesis. Most often, at least one of the contacted reagents may directly interact—undergo an electrochemical oxidation or reduction—with charges of an (active or counteractive) nanoelectrode, thereby yielding a change in reaction conditions (e.g. a change in the concentration of an active species, such as an electrochemical reagent or reaction product). Here, direct interaction with charges of the nanoelectrode may comprise interaction at the nanoelectrode surface as such or—away from the surface—with charges having migrated through the reaction medium. Regardless, based on the altered reaction conditions, one or more further chemical reactions—e.g. involving the reagents or reaction products of the first reaction and/or one or more further reagents—may then be enabled or disabled. Such further reagents may be added together with the initial electrochemically active reagent or may added at a later stage. To name but one example of indirect mediation, the generated reaction conditions (e.g. a lowered pH) may lead to deprotection of a reagent (e.g. a DNA strand) by removal of a protective group and then in turn further enable a synthetic reaction between the deprotected reagent (e.g. DNA synthesis) and one or more further reagents (e.g. a nucleotide).

In embodiments, the generated reaction conditions in step b may comprise a change in pH (e.g. by generating protons through the oxidation of hydroquinone or consumption of protons through the reduction of benzoquinone), generation of free radicals (e.g. by an electrochemically produced from persulfates), the generation of Cu-ions (e.g. for click chemistry) or the generation of divalent cations (e.g. to control an enzymatic reaction).

In embodiments, the method may further comprise a step c of: (c) withdrawing (e.g. washing away) one or more of the reagents. In embodiments, the method may comprise repeating a sequence of steps a, b and—optionally—c. In embodiments, the sequence of steps may be repeated an arbitrary number of times (cf. Example 4).

In embodiments, any feature of any embodiment of the fourth aspect may independently be as correspondingly described for any embodiment of any of the other aspects.

The disclosure will now be described by a detailed description of several embodiments of the disclosure. It is clear that other embodiments of the disclosure can be configured according to the knowledge of the person skilled in the art without departing from the true technical teaching of the disclosure, the disclosure being limited only by the terms of the appended claims.

### Example 1: Array with Physical Confinement of the Reaction Conditions

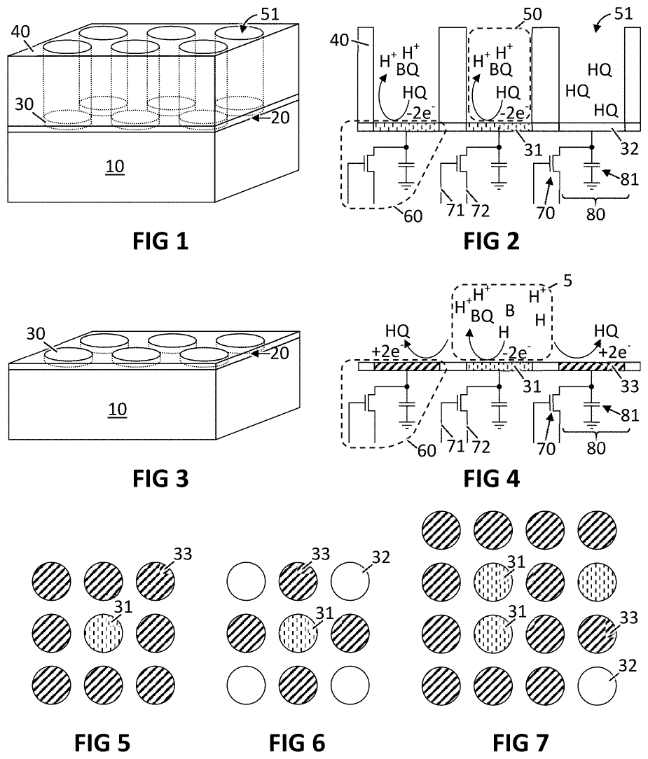

We now refer to FIG. 1, which depicts a 3D view of an array for molecular synthesis in which the reaction conditions are confined by physical means. To that end, the array comprises a nanoelectrode array (20) on a substrate (10) and a perforated cover layer (40) over the nanoelectrode array (20). The perforated cover layer (40) comprises cavities (51) which overlay and open up the nanoelectrodes (30) at the bottom thereof. As such, each cavity (51) forms a synthesis cell (50) in which the walls that define it hinder diffusion of the reaction medium from one synthesis cell (50) to the next, thereby locally confining the reaction medium—and thus the reaction conditions. One or more counter electrodes (not depicted), for example arranged in a counter electrode array, are also typically present. These may for example be situated above the nanoelectrode array (20) (e.g. atop the perforated cover layer (40) or further above)—in which case they may e.g. be parallel with nanoelectrodes (30)—or coplanar with the electrode array (20). Each nanoelectrode (30) is then typically associated with a counter electrode—although it is not excluded that one counter electrode may be associated with a plurality of nanoelectrodes (30)—and the electric potential difference developed between both of these governs the electrochemical reaction in the synthesis cell (50)

This is also illustrated in FIG. 2, where two active nanoelectrodes (31) are shown to electrochemically oxidize hydroquinone (HQ) to benzoquinone (BQ), thereby producing protons (W) and locally lowering the pH. Migration of the protons and other reaction products outside the synthesis cell (50) in which they are formed is however hindered by the walls of the perforated cover layer (40), so that they remain localized to the synthesis cell (50). Accordingly, a change in pH is not observed in the right-most synthesis cell (51), where the corresponding nanoelectrode (32) is inactive. This allows for control of—through setting the nanoelectrode (31, 32)—the reaction conditions (e.g. pH) in each synthesis cell (50) individually, thereby across the array managing where a reaction is enabled and where it is disabled.

FIG. 2 also shows more details of the electrode cells (60) with which the nanoelectrodes (31, 32) are addressed. Each electrode cell (60) comprises a storage circuit (80)—with the corresponding nanoelectrode (31, 32)—and an access transistor (70)—with a gate, a source, and a drain. Each nanoelectrode (31, 32) is then addressable through controlling the corresponding access transistor (70) in its electrode cell (60). More in particular, the potential of each nanoelectrode (31, 32) can be individually set by asserting the corresponding word line (71) to open the access transistor (70) and biasing the corresponding bit line (72) to charge the storage circuit (80). After disconnecting the access transistor (70), the charge stored by the storage circuit (80) can then be (e.g., slowly) used by the nanoelectrode (31, 32), e.g. to drive an electrochemical reaction. Moreover, even if not expended to drive an electrochemical reaction, slow—e.g. in the order of (tens of) milliseconds—depletion of the stored charge will typically occur; e.g. because of unavoidable leaks (cf. supra). Since the reaction time may typically be in the order of a fraction of a second to several seconds, the duration over which one may wish to maintain the potential will typically be longer than the retention/depletion time of the storage circuit (80). To remedy this, the nanoelectrodes (31, 32) can be periodically rewritten (i.e. re-set or recharged), thereby extending their duration (see also Example 3).

The storage circuit (80) depicted in FIG. 2 comprises a capacitor (81) of which one terminal is resistively coupled to both the drain and the nanoelectrode (31, 32). However, a separate capacitor (81) isn't strictly required and a sufficient storage capacitance in the storage circuit (80) could be achieved based on parasitic capacitance (e.g. wire capacitance) of the storage circuit (80) as such and/or a capacitor (81) formed about the electrical connection coupling the drain to the nanoelectrode (31, 32).

### Example 2: Array with Electrochemical Confinement of the Reaction Conditions

FIG. 3 depicts a similar 3D view as FIG. 1, but for an array in which confinement is achieved electrochemically. The array shown in FIG. 3 differs from the one in FIG. 1 in that it does not include the perforated cover layer (40). Instead, as illustrated in FIG. 4, confinement is achieved by setting the nanoelectrodes (33) surrounding the active nanoelectrodes (31) to be counteractive, so that the opposite reaction occurs there. In the example shown in FIG. 4, protons are generated by oxidizing hydroquinone to benzoquinone at the active nanoelectrode (31) and are consumed near the counteractive nanoelectrodes (33) in the reduction of benzoquinone back to hydroquinone. Thus, as the produced protons start to diffuse away from the active nanoelectrodes (31), they are consumed at the surrounding counteractive nanoelectrodes (33), thereby—even in the absence of physical boundaries—still confining the reaction conditions to the desired synthesis cells (50).

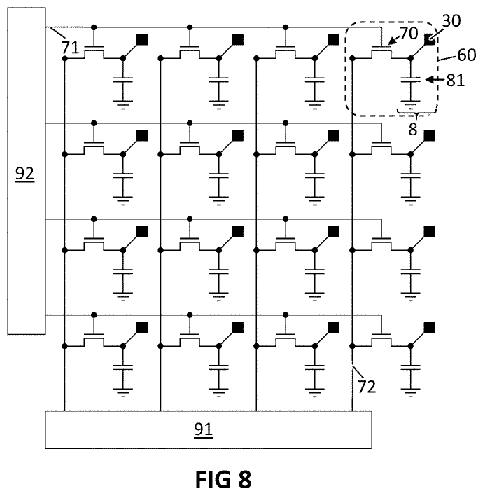

Surrounding of active nanoelectrodes (31) by counteractive nanoelectrodes (33) in a cubically packed array is also illustrated in the top views of FIG. 5, FIG. 6, and FIG. 7. FIG. 5 shows a single active nanoelectrode (31) surrounded by eight counteractive nanoelectrodes (33). However, as shown in FIG. 6, it may in embodiments be sufficient to set only the four immediately closest nanoelectrodes (33) to counteractive and to have the further nanoelectrodes (32) kept inactive. FIG. 7 illustrates a further situation in which two neighboring nanoelectrodes (31) are set to be active, the nanoelectrodes (33) surrounding the active nanoelectrodes (31) are set to be counteractive and the nanoelectrode (32) which is not active and not next to an active nanoelectrode (31) are set to be inactive.

The above notwithstanding, it will be clear that the cubic packing shown here is only illustrative and that other arrangements (e.g. a hexagonal packing) of the array can likewise envisioned.

### Example 3: Array of Electrode Cells

We now refer to FIG. 8, which schematically depicts an array of electrode cells (60), each electrode cell (60) comprising a storage circuit (80)—with a corresponding nanoelectrode (30)—and an access transistor (70). The electrode cells (60) are arranged in rows and columns, wherein the electrode cells (60) in a row are linked by a common word line (71) and in a column by a common bit line (72). The word lines (71) are coupled to a row address selector (92), while the bit lines (72) are coupled to a column address selector (91). Note however that the electrode cell array is again not limited to a cubic packing and that other arrangements (e.g. hexagonal packing) can likewise envisioned.

Akin to the operation of DRAM memory, setting the potential of the nanoelectrodes (30) may be performed through opening all access transistors (70) in a row by asserting the common word line (71) and, for each electrode cell (60) in the row, charging the storage circuit (80) by correspondingly biasing the associated bit line (72).

In order to maintain the potential for an extended duration (e.g. several seconds), the nanoelectrodes (30) can be periodically rewritten (i.e. re-set or recharged); not unlike a periodic memory refresh in DRAM. Note however that in the present disclosure, the stored charge in the storage circuit (80) will typically be used up (e.g. in electrochemical reactions) or will otherwise dissipate (e.g. through the reaction medium) over time. As such, contrary to a DRAM refresh, it may not be possible to read the potential to be set back out prior to rewriting it and that information may need to be retrieved or maintained elsewhere (e.g. the selected potential for each nanoelectrode may need to be stored separately for as long as this information is still needed).

Likewise, other strategies used to improve the operation of DRAM memory can also be used in the context of the present disclosure. For example, the system may comprise multiple arrays in a sub-banked arrangement, so that the arrays can be (re)written at the same time, thereby improving the throughput at low energy.

### Example 4: Using a System in Accordance with the Present Disclosure in Biological Synthesis

An array such as for example described in Example 1 and Example 2, may for instance be used in the synthesis of (synthetic) DNA or another (bio)molecule. A method for expanding one or more protected DNA strands may for example start with providing the protected DNA strand(s) in the synthesis cells over the nanoelectrodes (e.g. one strand per synthesis cell). Next, one or more reagents for—in combination with an active nanoelectrode—deprotecting the DNA strands may be provided in the reaction medium (e.g. a proton-generation agent, such hydroquinone, for the acid-based deprotection). A number of nanoelectrodes where a particular nucleotide is to be added can then be selected and the nanoelectrodes in the nanoelectrode array can be set accordingly (e.g. the corresponding nanoelectrodes can be activated and—e.g. in an array such as described in Example 2—the surrounding nanoelectrodes can be set to be counteractive). By doing so, the deprotection reaction is locally enabled and specifically the selected DNA strands can be deprotected, while leaving the other DNA strands protected. A derivative of the nucleotide—e.g. bearing a further protective group—can then be brought into the reaction medium and be reacted with the deprotected strands, resulting in selectively expanded strands which again bear a protective group. After washing away the nucleotide derivative, the procedure can be restarted—e.g. in order to add another nucleotide to the DNA strand(s)—and it can be repeated an arbitrary number of times to yield DNA strands with an arbitrary sequence. Note in particular that, since the strands to be expanded can be selected in every instance of the procedure, the sequence of DNA strands need not be the same. Indeed, the DNA strand above each nanoelectrode may have a unique sequence. As such, the array can be used to make a DNA data storage.

It is to be understood that although embodiments, specific constructions and configurations, as well as materials, have been discussed herein for devices according to the present disclosure, various changes or modifications in form and detail may be made without departing from the scope and technical teachings of this disclosure. For example, any formulas given above are merely representative of procedures that may be used. Functionality may be added or deleted from the block diagrams and operations may be interchanged among functional blocks. Steps may be added or deleted to methods described within the scope of the present disclosure.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. An array of individually addressable electrode cells, each electrode cell of the array comprising:
a storage circuit; and
a nanoelectrode that is resistively coupled to the storage circuit, the array being configured to independently control reaction conditions of each nanoelectrode of the electrode cells.

2. The array according to claim 1, wherein the storage circuit comprises a capacitor.

3. The array according to claim 2, each electrode cell of the array further comprising an access transistor, wherein the capacitor has a terminal resistively coupled to both a drain of the access transistor and to the nanoelectrode.

4. The array according to claim 3, wherein the access transistor is a back end of line (BEOL) transistor.

5. The array according to claim 1, wherein the electrode cells are arranged in one or more rows each linked by a word line and in one or more columns each linked by a bit line.

6. The array according to claim 1, further comprising a cover layer having cavities that are aligned with the nanoelectrode of each electrode cell of the array.

7. The array of claim 6, wherein the cover layer is configured to isolate reaction conditions of the nanoelectrode from the reaction conditions of other nanoelectrodes.

8. A method comprising:
changing an amount of electric charge stored within a storage circuit that is resistively coupled to a nanoelectrode, thereby causing reaction conditions of the nanoelectrode to change.

9. The method of claim 8, wherein causing the reaction conditions to change comprises changing a pH of a liquid adjacent to the nanoelectrode.

10. The method of claim 8, further comprising, simultaneously with changing the amount of electric charge stored within the storage circuit, changing a second amount of electric charge stored within a second storage circuit that is resistively coupled to a second nanoelectrode.

11. The method according to claim 8, wherein changing the amount of electric charge stored within the storage circuit comprises operating the nanoelectrode potentiostatically.

12. The method according to claim 8, wherein changing the amount of electric charge stored within the storage circuit comprises operating the nanoelectrode galvanostatically.

13. The method according to claim 8, wherein changing the amount of electric charge stored within the storage circuit comprises operating the nanoelectrode potentiodynamically.

14. The method of claim 8, further comprising:
contacting a reagent to the nanoelectrode prior to changing the amount of electric charge; and
generating a reaction product using the reagent, in accordance with the reaction conditions induced by the electric charge stored within the storage circuit.

15. The method according to claim 14, wherein generating the reaction product comprises generating DNA.

16. The method of claim 14, wherein changing the amount of electric charge comprises changing the amount of electric charge by adjusting a bias provided to a bit line resistively coupled to the storage circuit, wherein generating the reaction product comprises generating the reaction product such that the reaction product changes over time in accordance with the electric charge stored by the storage circuit over time.

17. The method of claim 8, wherein changing the amount of electric charge stored within the storage circuit comprises:
enabling a word line that is resistively coupled to the storage circuit; and
providing a bias to a bit line that is resistively coupled to the storage circuit to change the amount of electric charge stored within the storage circuit.

18. The method of claim 8, wherein the nanoelectrode is a first nanoelectrode, the method further comprising changing a second amount of electric charge stored within a second storage circuit that is resistively coupled to a second nanoelectrode, to electronically isolate the reaction conditions of the first nanoelectrode from reaction conditions of the second nanoelectrode.
